(19) United States
(12) Patent Application Publication
(10) Pub. No.: US 2024/0164050 A1
(43) Pub. Date: May 16, 2024

(54) BEZEL-MOUNTED ACOUSTIC FILTER FOR USE WITH RACK RAIL-MOUNTED CHASSIS

(71) Applicant: SANMINA CORPORATION, San Jose, CA (US)

(72) Inventors: Odie Banks Killen, JR., Colorado Springs, CO (US); Daniel Joseph Gregory, Colorado Springs, CO (US)

(21) Appl. No.: 17/985,030

(22) Filed: Nov. 10, 2022

(51) Int. Cl. H05K 7/20

(52) U.S. Cl. CPC H05K 7/20172; H05K 7/20181; H05K 7/20736

(57) ABSTRACT

According to an aspect a bezel-mounted acoustic filter is provided for use with rack rail-mounted chassis. A rack-mount component has a front side and a back side and includes electronics in the component. A fan is configured to draw air through the front side and across the electronics. An acoustic filter is at the front side and positioned so that that the fan draws the air through the acoustic filter to the fan.

### FIELD

The present description relates to equipment in rack rail-mounted chassis systems and in particular to cold aisle acoustic filtering for use in such systems.

### BACKGROUND

Rack-mount components are used for data storage, data servers, data processing, communications, audio and video processing and other applications. A typical installation will have rows of vertical four-post racks with rails running from side-to-side and front to rear between the four posts of each rack. Static rails are fixed in place and are typically bolted to the vertical posts. Sliding rails have one part that bolts to the vertical rack and another part that glides forward or back for access. The components mount to the rails one on top of the other and are arranged with ports and connectors on the back side and status displays and controls on the front side, although there may be a few ports and connectors on the front side and status indicators on the rear for quick access. The ports and connectors allow the components to be coupled together with cabling for data, power, interface, and communications.

A typical installation will have rows of vertical racks with fans drawing air into racks on both sides of the cold aisles, which are often used as the service aisles for many tasks. The cold air is drawn through the front side of the electronics and pushed out to a hot aisle on the back side. The hot aisles can have rows of racks on both sides pushing air into the hot aisles. Hot air is evacuated from the hot aisles by a building heating, ventilation, and air-conditioning (HVAC) system and then typically the newly cooled air is poured back into the cold aisles. The electronics are designed so that most of the operations and management work can be conducted from the cold aisle side. In this way, operations personnel work mostly in the cold aisle.

### BRIEF SUMMARY OF SOME EXAMPLES

The following presents a summary of one or more aspects of the present disclosure, in order to provide a basic understanding of such aspects. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in a form as a prelude to the more detailed description that is presented later.

According to an aspect a bezel-mounted acoustic filter is provided for use with rack rail-mounted chassis. A rack-mount component has a front side and a back side and includes electronics in the component. A fan is configured to draw air through the front side and across the electronics. An acoustic filter is at the front side and positioned so that that the fan draws the air through the acoustic filter to the fan.

The acoustic filter may be configured in a form of a bezel to cover the front side of the component. A bezel may be positioned, coupled, or configured to cover the front side of the component, wherein the bezel is configured to hold the acoustic filter between the bezel and the fan. The bezel may hold the acoustic filter with a friction fit. The bezel may be positioned, coupled, or configured to hold a second acoustic filter between the bezel and the fan. The second acoustic filter may have different acoustic properties from the first acoustic filter. The bezel may be positioned, coupled, or configured to hold a third acoustic filter between the bezel and the fan, wherein the first acoustic filter, the second acoustic filter, and the third acoustic filter each target a different specific frequency range. The bezel may be positioned, coupled, or configured to hold a dust filter between the bezel and the fan.

The acoustic filter may be positioned, coupled, or configured to extend across the front side of the component. The bezel may include an end cap at each end of the bezel, wherein the end caps include clips to attach the bezel to the component. The fan may be positioned, coupled, or configured to push air out the back side.

The filter may have perforations configured to allow air to flow through the filter to the fan. The perforations may be positioned, coupled, or configured as hexagon cells in a honeycomb structure. The perforations may be positioned, coupled, or configured in a shape of round holes.

According to another aspect a rack-mount component is provided having a front side and a back side. The component includes electronics in the component, a fan configured to draw air through the front side and across the electronics, and means for filtering sound from exiting the front side and positioned so that that the fan draws the air through the means for filtering. The component may include means for attaching the means for filtering across the front side of the component over the fan. The component may include means for covering the front side of the component and the means for filtering may be positioned, coupled, or configured to be attached to the means for covering. In some aspects the means for filtering further includes an end cap at each end of the means for filtering, wherein the end caps include clips to attach the means for filtering to the means for filtering.

According to another aspect, a rack-mount server has a front side configured to face a cold aisle and a back side configured to face a hot aisle. The server includes electronics in the server, a plurality of front fans attached to the front side of the server and configured to draw air through the front side and across the electronics of the server to be pushed out the back side of the server into the hot aisle, a bezel extending across the front side of the server and covering the plurality of fans, and an acoustic filter attached to the bezel and extending across the plurality of fans air drawn through the front side is drawn through the acoustic filter to the fan. The acoustic filter may include a polyurethane foam having hexagon cells in a honeycomb structure.

### BRIEF DESCRIPTION OF THE DRAWINGS

FIG. 1 is a diagram of a rack-mount component system inside an enclosed structure with a hot aisle and a cold aisle.

FIG. 2 is a partially exploded isometric diagram of a rack-mount component with an acoustic filter configured as a bezel.

FIG. 3 is an exploded isometric diagram of a bezel that is configured to hold an acoustic filter.

FIG. 4 is an isometric front view diagram of the bezel holding an acoustic filter with a bezel shroud fully assembled.

FIG. 5 is an isometric rear view diagram of the bezel holding an acoustic filter with a bezel shroud fully assembled.

FIG. 6 is an exploded isometric diagram of a bezel and multiple filters.

FIG. 7 is a plan view of a diagram of an acoustic filter with a honeycomb structure.

FIG. 8 is an angled view diagram of an acoustic filter with a honeycomb structure.

FIG. 9 is a plan view diagram of a round acoustic filter structure.

FIG. 10 is a front plan view diagram of front side of a component with a bezel and an acoustic filter.

### DETAILED DESCRIPTION OF THE INVENTION

The word “exemplary” or “embodiment” is used herein to mean “serving as an example, instance, or illustration.” Any implementation or aspect described herein as “exemplary” or as an “embodiment” is not necessarily to be construed as preferred or advantageous over other aspects of the disclosure. Likewise, the term “aspects” does not require that all aspects of the disclosure include the discussed feature, advantage, or mode of operation.

Embodiments will now be described in detail with reference to the accompanying drawings. In the following description, numerous specific details are set forth in order to provide a thorough understanding of the aspects described herein. It will be apparent, however, to one skilled in the art, that these and other aspects may be practiced without some or all of these specific details. In addition, well known steps in a method of a process may be omitted from flow diagrams presented herein in order not to obscure the aspects of the disclosure. Similarly, well known components in a device may be omitted from figures and descriptions thereof presented herein in order not to obscure the aspects of the disclosure.

In the following detailed description, numerous specific details are set forth in order to provide a thorough understanding of the different aspects. However, it will be understood by one of ordinary skill in the art that the different aspects may be practiced without these specific details. For example, well-known operations, structures, and techniques may not be shown in detail in order not to obscure the different aspects presented herein.

As described herein, an acoustic filter is placed in the airflow path between the cold aisle and noise sources that are part of a rack-mounted component. For a component with front-mounted fans this location is between the cold aisle and front-mounted fans to attenuate acoustic energy that travels from the fans to the cold aisle. This reduces the noise energy in the data center cold aisle.

Rack-mount electronics generate significant noise mostly from fans that draw air from the cold aisle across the electronics to the hot aisle. To reduce noise in the cold aisle, fans are typically placed on the back side of the electronics, the side farthest from the cold aisle. As the electronics increase in performance and shrink in size, more airflow is used to compensate for the greater amount of heat generated in a smaller space.

As the density of server processing and storage enclosures increases. airflow through the enclosures is increased to compensate for the increased heat generated by the higher density and higher total power of the components. Smaller components use smaller fans which make more noise for the same amount of air flow. With hard disk storage arrays and some other components, the hard disk drives also contribute to the total noise. In some instances fans, are also placed in the middle of the enclosure to generate still more air flow without interfering with back side cable connectors.

Recently, to provide even more airflow, fans are also being placed at or near the front side of the enclosures. Fans near the front side are closer to the cold aisle, which is often the service aisle of the data center. The fan noise is now much closer to the data center service personnel. Noise generation in the cold aisle is a significant concern for data center operators and staff. When data center service personnel are subjected to unwanted noise and acoustic energy for long periods of time, real and lasting injury may occur.

As described herein, an acoustic filter is placed between the fans and the cold aisle to reduce the acoustic energy that is incident on the cold aisle. This reduces the acoustic and noise levels produced. In some examples, the filter is an insert into an existing bezel. In some examples, the filter is formed by the bezel itself. Acoustic foam can be molded into a bezel insert and may be used together with a dust filter insert. Acoustic foam can also be molded into a shape to be the bezel itself.

The filter can be made out of a cut and punched sheet, a stack of cut and punched sheets. The sheets may be made of any of a variety of different acoustic dampening materials, for example from molded acoustic foams. The acoustic filter is placed directly in the airflow path between the cold aisle and the fans. For air to freely pass through the filter, in some examples, the acoustic filter has a perforation pattern. Any one of a number of common patterns may be used, for example, a honeycomb, squares, rectangles, circles etc.

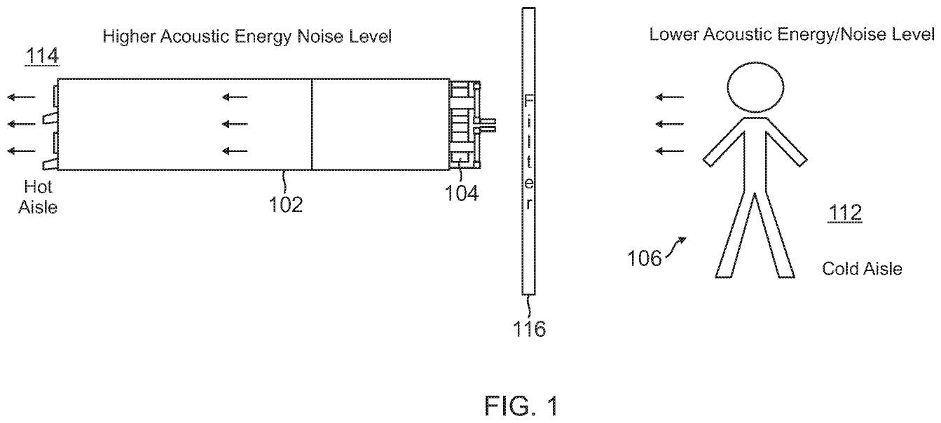

FIG. 1 is a diagram of a rack-mount component system inside an enclosed structure with a hot aisle and a cold aisle. A component 102, illustrated as a single enclosure generates heat from electronics inside the enclosure that perform data processing, data storage operations, data communications, or other operations. The component has a front fan 104 at a front side that draws air from a cold aisle 112 across the component 102 out a back side to a hot aisle 114. The cold air is heated as it is drawn across the component 102. The front fan 104, together with the data processing, data storage operations, and data communications, generate significant acoustic noise or acoustic energy. An operator 106 operates on the component 102 in the cold aisle. An acoustic filter 116 between the front fan 104 and the operator 106 protects the operator 106 from the acoustic noise of the component 102 and its front fan 104.

The acoustic filter 116 is perforated to allow air from the cold aisle 112, where the operator 106 is, to pass through the acoustic filter 116 to reach the front fan 104. At the same time, the acoustic filter 116 absorbs acoustic energy emitted by the component 102 before it reaches the operator 106. In many circumstances, operations personnel work primarily in the cold aisle 112. Accordingly, the acoustic filter 116 provides a significant benefit to the operator 106 and allows the use of front fans 104 which might otherwise emit too much noise for safe use in the structure. The diagram is simplified for ease of understanding. In many implementations, there are many racks, each carrying many rack-mount components. There may also be many aisles. Aisles are typically arranged so that there are two rows of racks, one row on each side of the aisle, each with component front sides facing the cold aisle from opposite sides of the aisle. The hot aisle similarly has two rows of racks, one on each side, each row with component back sides facing the hot aisle.

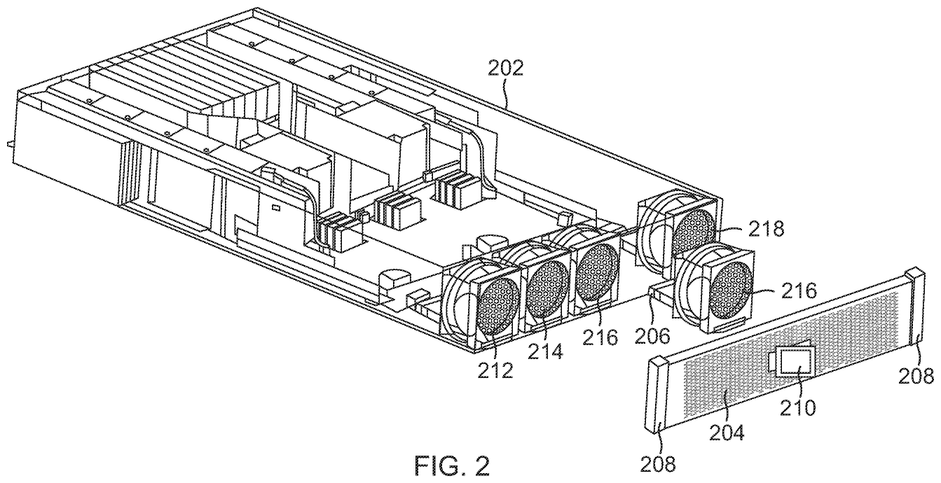

FIG. 2 is a partially exploded isometric diagram of a rack-mount component with an acoustic filter configured as a bezel. A component 202, in this case having a 2U enclosure, approximately 3½ inches (88 mm) high, has a cabinet with various data processing, data storage, and communications equipment. The component has a bracket (not shown) across the front to support a row of fans 212, 214, 216, 218, e.g. 60 mm to 80 mm fans. In this example, there are five fans across the entire width of the component, which may be 19 inches (482 mm) wide. The fans are each carried in a housing with a shroud and mounting bracket 206 to attach to the component. The fans are configured to draw air through the front side of the component from the cold aisle. The fans are configured to push air out the back side of the component to the hot aisle.

A bezel 204 attaches across the row of fans 212, 214, 216, 218. The bezel 204 may be removed, as shown, to allow a fan 216 to be removed from the component 202. The fan 216 may be replaced or repaired and the bezel 204 replaced. Removing one or more of the fans may also allow electronics and other parts of the component to be accessed behind the fans. While five fans are shown, more or fewer fans may be used to suit different component requirements. Additional fans may be placed at the rear of the component and in intermediate locations within the component. While a server is shown, any other rack-mount component may be implemented in the same or a similar way including mass data storage devices, communications devices, switching devices, and audio and video equipment.

The bezel 204 is configured as an acoustic filter that is permeable due to a pattern of openings or holes through the bezel to the fans. The bezel 204 has end caps 208 on either side of a main body and a nameplate 210. The end caps may provide for attaching the bezel 204 to the component 202 using clips, springs, clamps, or discrete fasteners. Alternatively, the bezel may have multiple or central attachment points or a frame may be used to hold the bezel against the component. The main body of the bezel 204 is formed of a foam, mesh, or other material that absorbs or reflects sound or both from the component to prevent at least a portion of that sound from going to the cold aisle in front of the bezel. In other words, the bezel is integrated with the acoustic filter. Alternatively, as described below, the bezel 204 holds an acoustic filter between the bezel and the fan to absorb acoustic energy from the component, including from the front fans while allowing air to pass through the bezel and through the acoustic filter from the cold aisle to the fans.

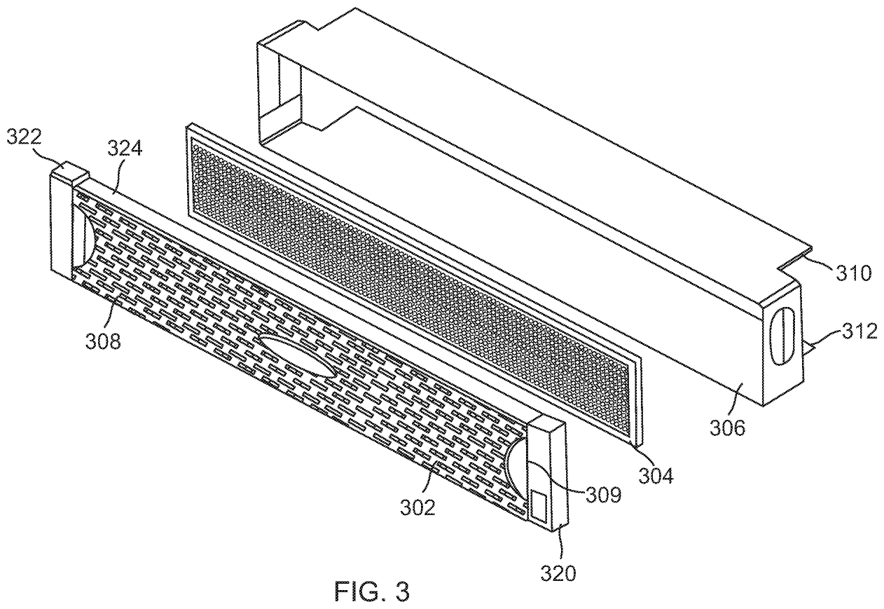

FIG. 3 is an exploded isometric diagram of a bezel that is configured to hold an acoustic filter. The bezel 302 extends across the front of a component, for example the front side of the component 202 of FIG. 2. The bezel 302 may be formed of any suitable material, for example metal or plastic, and may include name plates 318, labels and aesthetic details. The bezel includes a mesh, screen or grille 308 to allow air to flow freely through the bezel. The bezel also includes one or more openings 309 to allow air flow and to serve as handles to grasp the bezel for removal and installation. The bezel 302 may serve as a protective cover for any moving parts, electrical parts, or electronics within the component to which it is attached. A right cap 320 and left cap 322 attached to the bezel 302 at each end are configured to attach to the component. A variety of different attachment mechanisms may be used. In one example, there are clips (not shown) integrated into the right cap 320 and the left cap 322 that attach to ball studs on rack ears the component or a canister. The ball studs may extend laterally or transversely to suit the configuration of the clips. In another example, the right cap and end cap have clips to attach over tabs on the component. The bezel has side walls 324 along a top edge and a bottom edge (not visible) of the bezel extending about perpendicular from the main body of the bezel. The side walls 324 form ledges between which an acoustic filter 304 may be secured.

The acoustic filter 304 is configured to fit against the main body of the bezel and between the side walls 324 at the top edge and the bottom edge. The acoustic filter is also configured to fit between the right cap 320 and the left cap 322. As shown, the acoustic filter extends across the entire width of the bezel between the right cap 320 and the left cap 322 so that the acoustic filter covers all five fans. However, the acoustic filter may be adapted to suit different bezels and components and different fan configurations.

The acoustic filter 304 may be attached to the bezel 302 as a snug fit using low interference without any specific fasteners to retain the acoustic filter 304 into the bezel 302. A friction fit may be sufficient to secure the acoustic filter 304 for many implementations. Alternatively, fasteners may be used such as clips, screws, magnets, etc. to secure the acoustic filter more securely.

In the component 202 of FIG. 2, five fans 212, 214, 216, 218 are arrayed across substantially the whole width of the component 202. The acoustic filter 304 is configured to extend across all of the fans between the fans and the bezel. In this way, acoustic energy from any one or more of the five fans must pass through the acoustic filter to pass through the bezel on the front side of the component. This allows the acoustic energy to be absorbed before arriving at an operator near the front side of the component.

The bezel 302 and acoustic filter 304 attach to a bezel shroud 306. The bezel shroud 306 has an upper tab 310 and a lower tab 312 that are configured to extend into the front side of a component to guide the bezel 302 and the acoustic filter 304 into the front of the component between any fans of the component. This puts the acoustic filter 304 between any fans or other internal parts and an operator. The bezel shroud has walls on four sides around the bezel including the upper tab 310 and the lower tab 312 that serve to guide air toward the fans and guide acoustic energy through the acoustic filter 304. The bezel shroud may be modified to suit other component configurations and for canisters and trays when components are carried by canisters or trays.

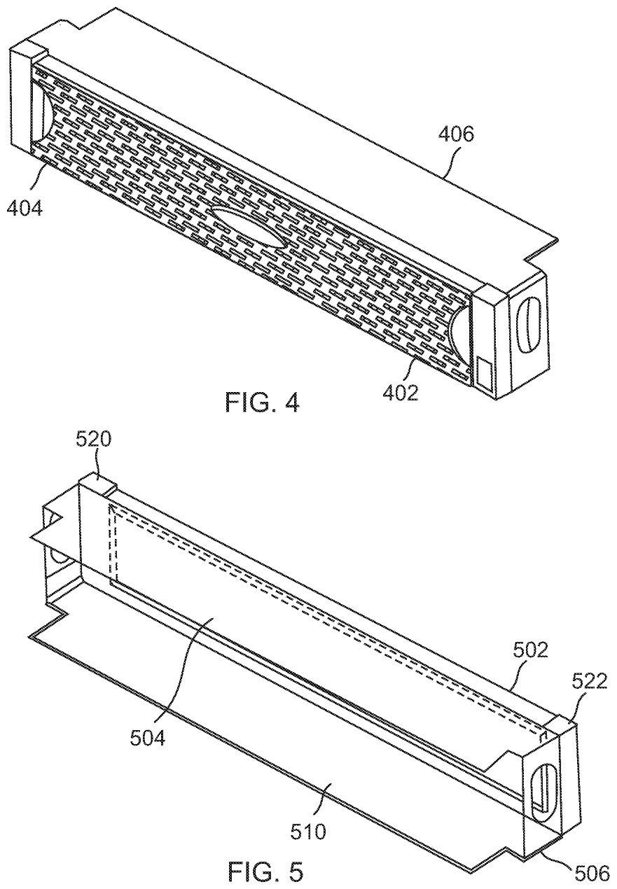

FIG. 4 is an isometric front view diagram of the bezel holding an acoustic filter with a bezel shroud fully assembled. A bezel 402 has a mesh, screen, or grille to allow airflow through the bezel and an acoustic filter 404. The bezel is attached to a bezel shroud 406. The bezel shroud is configured to attach to a rack-mount component.

FIG. 5 is an isometric rear view diagram of the bezel holding an acoustic filter with a bezel shroud fully assembled. A bezel 502 has a right cap 520 and a left cap 522 on either side of an acoustic filter 504 that is positioned against the bezel between the right cap 520 and the left cap 522. A bezel shroud 506 is attached to the bezel 502 and the acoustic filter 504.

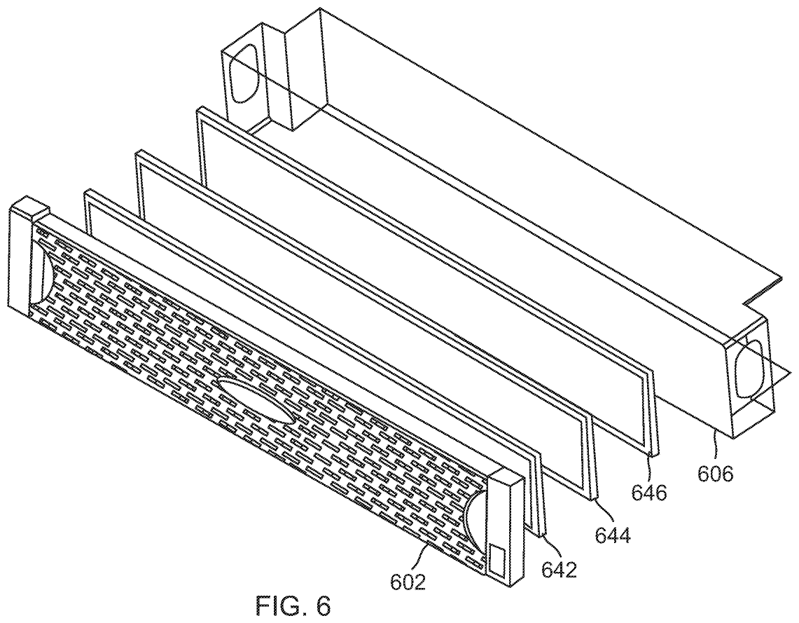

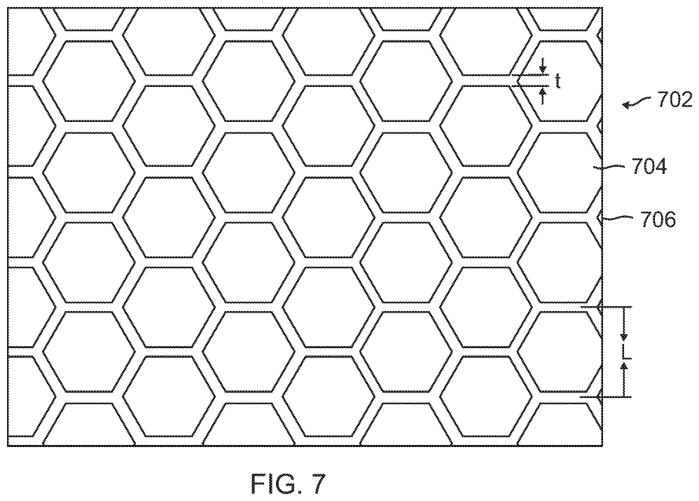

FIG. 6 is an exploded isometric diagram of a bezel and multiple filters. A bezel 602 is configured to extend across a front side of a rack-mount component. The bezel attaches to a bezel shroud 606 that serves as a bracket to position the bezel 602 and filters in place with respect to the rack-mount component. A first acoustic filter 642, a second acoustic filter 644, and a third acoustic filter 646 are each configured to be retained against the bezel 602 so that when the bezel 602 is attached to a front side of the rack mount component, the filters 642, 644, 646 are between the component and the bezel. The filters are also between any fans and electrical noise-producing parts of the component and an operator. The bezel may be attached to the component or a canister with clips and pins (not shown) as described above or in another way. In an alternative example, the bezel attaches to the bezel shroud and the bezel shroud is attached to the component,

The filters 642, 644, 646 may be configured to serve different filter purposes. In an example, each filter absorbs different acoustic energy frequencies so that the first acoustic filter 642 absorbs more of a first acoustic frequency and the second acoustic filter absorbs more of a second acoustic frequency. As a result, the range of acoustic frequencies absorbed is greater than with a single acoustic filter. As an example, each acoustic filter may have features with particular dimensions and materials to correspond to particular resonant frequencies so that the resonant frequencies are absorbed more than other frequencies. The different filters may have different dimensions, different materials or both to be optimized for particular frequencies that are expected from the component. In another example, one of the filters absorbs dust and other particles in the airflow through the bezel 602 to the component. In another example, the filters are formed of different acoustic filter materials and have different acoustic properties. In some examples, the first acoustic filter, the second acoustic filter, and the third acoustic filter each target a different specific frequency range. In this way, a multiple stage filter may be created that has a layer that targets a specific frequency range allowing for broad band acoustic filters as well as high attenuation, narrow band acoustic filters. In some examples, a broad band acoustic filter may be used with a narrow band acoustic filter within the same bezel. This allows for general attenuation with specific attenuation to particular problem frequency ranges.

In use, air is drawn from the cold aisle through a mesh 604 in the bezel 602 by fans of the component. Air is also pushed out the back side of the component through other vents or opening in the component. The fans may be rear fans, middle fans, front fans, or some combination. The air serves to cool the component and is exhausted by being pushed out the rear of the component into the hot aisle. The filters 642, 644, 646 are formed of a material that allows air to flow through the filters to the component behind the filters and the bezel 602. At the same time, acoustic energy from the component is absorbed by one or more of the filters 642, 644, 646 so that less of the acoustic energy passes in the opposite direction from the component to the cold aisle.

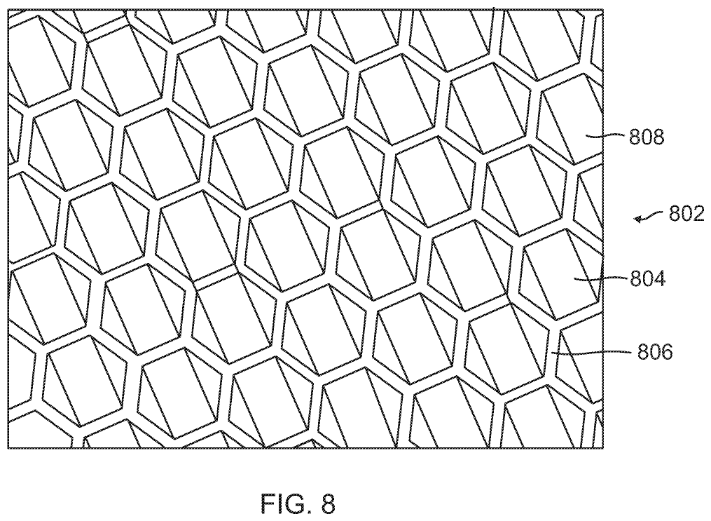

FIG. 7 is a plan view of a diagram of an acoustic filter with a honeycomb structure. A perforated acoustic filter 702 is configured with perforations in the form of an array of hexagon cells 704. The hexagon cells 704 are openings defined by filter material that forms the walls 706 of each hexagon. The hexagon cells 704 are in a honeycomb structure so that each of the six equal sides of each equilateral hexagon of a hexagon cell is shared with or in common with a different adjacent hexagon. In the honeycomb structure, a horizontal line through a center of a hexagon cell meets the top and bottom walls of the adjacent hexagon cells on both sides. The openings allow air to flow through the filter to or from a fan of a rack-mount component. The walls provide structure and sound absorption. The honeycomb structure provides high strength for the amount of material in the walls. The honeycomb structure also provides large openings for the amount of wall material in comparison to many other shapes.

The size and depth of the hexagon cells may be configured to absorb or dampen selected frequencies that are particularly notable in the noise profile of the component. These frequencies may correspond to resonant frequencies within the component or measured characteristics of the fans. In one example, each hexagon cell has a length, L, between parallel sides of about 4.5 mm. The walls may have a thickness, t, of about 0.5 mm. The thickness of the material may also be adapted to suit different component noise profiles. In some examples, the filter material may be about 20 mm to 50 mm thick. The configuration and size of the honeycomb cells may be adapted to suit different components and different sized components, e.g., a 1U component vs. a 4U component.

FIG. 8 is an angled view diagram of an acoustic filter with a honeycomb structure. A perforated acoustic filter 802 is provided with perforations in a honeycomb structure in which the walls 806 of each hexagon cell define an opening 804 through which air may flow to or from a fan positioned near the acoustic filter. In this angled view, the walls 806 are shown as having a depth that extends through the filter material. The acoustic filter material has hexagonal cross sections for which the sides of each hexagon form straight hexagonal tubes 808 through the acoustic filter. The additional surface area provided by the depth of the tubes improves the filtering capability of the acoustic filter by presenting more acoustic filter surface to the acoustic energy that is propagating through tubes 808.

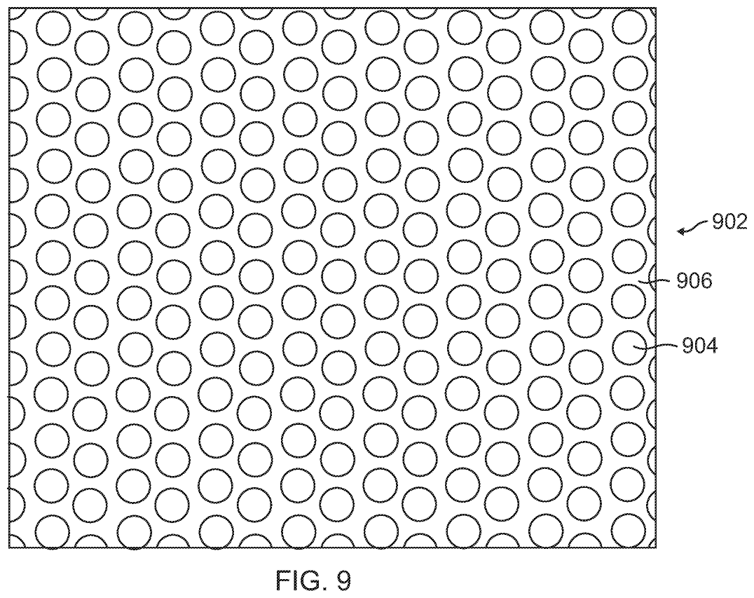

FIG. 9 is a plan view diagram of a round acoustic filter structure. A perforated acoustic filter 902 is configured with perforations as an array of round holes or tubes 904 defined by round tubular side walls 906 which fill in the space between each circle. The round holes are aligned in alternating rows or columns so that the center of a circle is adjacent to a space between two circles to the left and the to the right. The alternating columns of circles allow the tubes 904 in the shape of round holes to be placed closer together while maintaining a significant amount of material in the walls 906. The structure and materials may be similar to that of the hexagon cells 704 of the honeycomb structure of FIG. 7. The shape of round holes are configured to allow air to flow through the round holes to or from a fan. The round holes provide good airflow while allowing for significantly more material in the walls 906 than for a honeycomb structure. For a material that absorbs acoustic energy better with thicker walls, the round structure may be more effective than the honeycomb structure which has thinner walls. Alternatively, the honeycomb structure may be made with thicker walls than those shown.

The choice of structure and the shape of the perforations may be affected at least in part by the choice of material. Many other configurations may be used other than hexagonal and round. The illustrated patterns allow air to flow through the tubes with only modest resistance. The acoustic filter is referred to as perforated to describe its final structure. The acoustic filter may be formed with perforations by molding, casting, deposition, extruding, weaving, or other techniques. Alternatively, the perforations may be formed by piercing a solid sheet.

The acoustic filter may be made of any suitable material. The material may include one or more of aluminum, polyurethane, polycarbonate, polypropylene, polyester, and other polymers. The polymers may be made into a foam such as a polyurethane foam, polypropylene foam, a polyester foam, or other foam. The foam may be produced in sheets that are cut to fit within a suitable bezel, e.g., by laser cutting or another cutting technology. In another example, the acoustic filter is produced using a moldable foam that is formed in a mold having a suitable shape for the placements described herein.

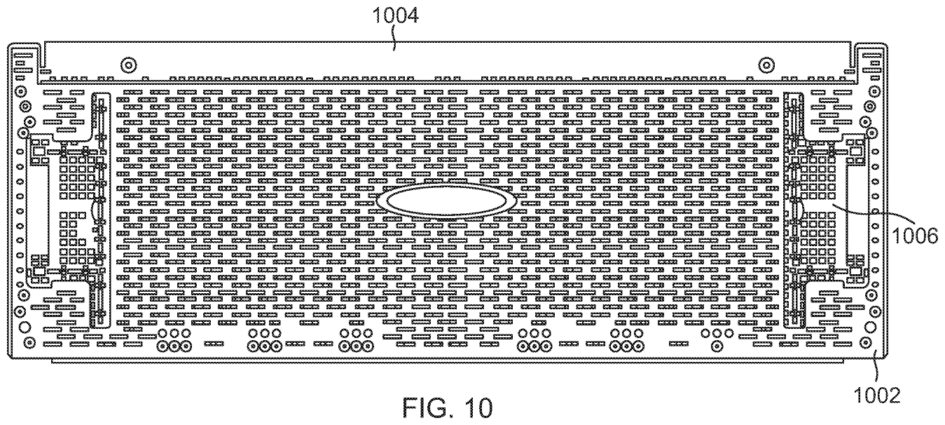

FIG. 10 is a front plan view diagram of front side of a component with a bezel and an acoustic filter. A bezel 1002 extends across the front of a component 1004. The bezel 1002 may be formed of any suitable material, for example metal or plastic, and may include name plates, labels and aesthetic details. The bezel 1002 has a mesh, screen, or grille to allow air to flow freely through the bezel and may also have openings (not shown). The bezel 1002 may serve as a protective cover and as a retainer for an acoustic filter 1006. A ledge extends around the side and bottom edges of the bezel to close over and attach to the component 1004. The bezel may be removed to allow the component to be serviced.

An acoustic filter 1006 is configured to fit against the main body of the bezel and between the right and left side ledges behind the bezel. As shown, the acoustic filter 1006 extends across the entire width of the bezel. However, the acoustic filter 1006 may be adapted to suit different bezels and components and different fan configurations. Any of a variety of fan arrays (not shown) may be installed behind the bezel 1002 and the acoustic filter 1006. In this way, acoustic energy from the fans must pass through the acoustic filter to pass through the bezel on the front side of the component. This allows the acoustic energy to be absorbed before arriving at an operator near the front side of the component.

The component 1004 has a 4U rack-mount height, of about 7 inches (178 mm), and a standard 19 inch (482 mm) width. The 2U component and the 4U component show how the acoustic filters described herein may be adapted to suit different sizes of components. Many other sizes including half-rack sizes may also be accommodated. The 4U component may have an array of four 120 mm fans or three 160 mm fans. In some 4U components there are two rows of five 60 mm or 80 mm fans. Other components may have other fan arrangements. Regardless of the number, position, and types of fans behind the bezel, the airflow from the front of the component is through the bezel and through the acoustic filter to reach the fans. Any noise from the fans travels through the acoustic filter and the front of the component to reach an operator.

The acoustic filter in the airflow path, as described, allows for enhanced airflow, particularly with front side fans, with much less noise in the cold aisle. High thermal performance can be obtained with a significant acoustic reduction.

As may be used herein, the term “operable to” or “configurable to” indicates that an element includes one or more of components, attachments, circuits, instructions, modules, data, input(s), output(s), etc., to perform one or more of the described or necessary corresponding functions and may further include inferred coupling to one or more other items to perform the described or necessary corresponding functions. As may also be used herein, the term(s) “coupled”, “coupled to”, “connected to” and/or “connecting” or “interconnecting” includes direct connection or link between nodes/devices and/or indirect connection between nodes/devices via an intervening item (e.g., an item includes, but is not limited to, a component, an element, a circuit, a module, a node, device, network element, etc.). As may further be used herein, inferred connections (i.e., where one element is connected to another element by inference) includes direct and indirect connection between two items in the same manner as “connected to”. As may be used herein, the terms “substantially” and “approximately” provide an industry-accepted tolerance for its corresponding term and/or relativity between items.

The various features of the disclosure described herein can be implemented in different systems and devices without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

In the foregoing specification, certain representative aspects of the invention have been described with reference to specific examples. Various modifications and changes may be made, however, without departing from the scope of the present invention as set forth in the claims. The specification and figures are illustrative, rather than restrictive, and modifications are intended to be included within the scope of the present invention. Accordingly, the scope of the invention should be determined by the claims and their legal equivalents rather than by merely the examples described. For example, the components and/or elements recited in any apparatus claims may be assembled or otherwise operationally configured in a variety of permutations and are accordingly not limited to the specific configuration recited in the claims.

Furthermore, certain benefits, other advantages and solutions to problems have been described above with regard to particular embodiments; however, any benefit, advantage, solution to a problem, or any element that may cause any particular benefit, advantage, or solution to occur or to become more pronounced are not to be construed as critical, required, or essential features or components of any or all the claims.

As used herein, the terms “comprise,” “comprises,” “comprising,” “having,” “including,” “includes” or any variation thereof, are intended to reference a nonexclusive inclusion, such that a process, method, article, composition or apparatus that comprises a list of elements does not include only those elements recited, but may also include other elements not expressly listed or inherent to such process, method, article, composition, or apparatus. Other combinations and/or modifications of the above-described structures, arrangements, applications, proportions, elements, materials, or components used in the practice of the present invention, in addition to those not specifically recited, may be varied or otherwise particularly adapted to specific environments, manufacturing specifications, design parameters, or other operating requirements without departing from the general principles of the same.

Moreover, reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is intended to be construed under the provisions of 35 U.S.C. § 112(f) as a “means-plus-function” type element, unless the element is expressly recited using the phrase “means for” or, in the case of a method claim, the element is recited using the phrase “step for.”

What is claimed is:

1. A rack-mount component having a front side and a back side, the component comprising:
electronics in the component;
a fan configured to draw air through the front side and across the electronics; and
an acoustic filter at the front side and positioned so that that the fan draws the air through the acoustic filter to the fan.

2. The component of claim 1, wherein the acoustic filter is configured in a form of a bezel to cover the front side of the component.

3. The component of claim 1, further comprising a bezel to cover the front side of the component, wherein the bezel is configured to hold the acoustic filter between the bezel and the fan.

4. The component of claim 3, wherein the bezel holds the acoustic filter with a friction fit.

5. The component of claim 3, further comprising a second acoustic filter and wherein the bezel is configured to hold the second acoustic filter between the bezel and the fan.

6. The component of claim 5, wherein the second acoustic filter has different acoustic properties from the first acoustic filter.

7. The component of claim 5, further comprising a third acoustic filter, wherein the bezel is configured to hold the third acoustic filter between the bezel and the fan, wherein the first acoustic filter, the second acoustic filter, and the third acoustic filter each target a different specific frequency range.

8. The component of claim 3, further comprising a dust filter and wherein the bezel is configured to hold the dust filter between the bezel and the fan.

9. The component of claim 1, wherein the acoustic filter extends across the front side of the component.

10. The component of claim 1, wherein the bezel includes an end cap at each end of the bezel, wherein the end caps include clips to attach the bezel to the component.

11. The component of claim 1, wherein the fan is further configured to push air out the back side.

12. The component of claim 1, wherein the filter comprises perforations configured to allow air to flow through the filter to the fan.

13. The component of claim 12, wherein the filter comprises perforations configured as hexagon cells in a honeycomb structure.

14. The component of claim 12, wherein the filter comprises perforations in a shape of round holes.

15. A rack-mount component having a front side and a back side, the component comprising:
electronics in the component;
a fan configured to draw air through the front side and across the electronics; and
means for filtering sound from exiting the front side and positioned so that that the fan draws the air through the means for filtering.

16. The component of claim 15, further comprising means for attaching the means for filtering across the front side of the component over the fan.

17. The component of claim 15, further comprising means for covering the front side of the component and wherein means for filtering is configured to be attached to the means for covering.

18. The component of claim 15, wherein the means for filtering further comprises an end cap at each end of the means for filtering, wherein the end caps include clips to attach the means for filtering to the means for filtering.

19. A rack-mount server having a front side configured to face a cold aisle and a back side configured to face a hot aisle, the server comprising:
electronics in the server;
a plurality of front fans attached to the front side of the server and configured to draw air through the front side and across the electronics of the server to be pushed out the back side of the server into the hot aisle;
a bezel extending across the front side of the server and covering the plurality of fans; and
an acoustic filter attached to the bezel and extending across the plurality of fans air drawn through the front side is drawn through the acoustic filter to the fan.

20. The server of claim 19, wherein the acoustic filter comprises a polyurethane foam having hexagon cells in a honeycomb structure.
